(19) United States
(12) Patent Application Publication
(10) Pub. No.: US 2013/0087097 A1
(43) Pub. Date: Apr. 11, 2013

(54) FILM DEPOSITION APPARATUS AND SUBSTRATE PROCESSING APPARATUS

(71) Applicants: Hitoshi KATO, Iwate (JP); Takeshi Kobayashi, Iwate (JP); Hiroyuki Kikuchi, Iwate (JP); Shigehiro Miura, Iwate (JP)

(72) Inventors: Hitoshi KATO, Iwate (JP); Takeshi Kobayashi, Iwate (JP); Hiroyuki Kikuchi, Iwate (JP); Shigehiro Miura, Iwate (JP)

(73) Assignee: Tokyo Electron Limited, Tokyo (JP)

(21) Appl. No.: 13/644,697

(22) Filed: Oct. 4, 2012

(30) Foreign Application Priority Data
Oct. 7, 2011 (JP) 2011-223067

(51) Int. Cl. C23C 16/50; C23C 16/52; C23C 16/458

(52) U.S. Cl. 118/663; 118/719

(57) ABSTRACT

An apparatus is configured to include a gas supplying part configured to supply a plasma generating gas on a surface on a substrate mounting area side in a turntable and an antenna configured to convert the plasma generating gas to plasma by induction coupling and provided facing the surface of the substrate mounting area side in the turntable so as to extend from a center part to an outer edge part of the turntable. The antenna is arranged so as to have a distance from the turntable in the substrate mounting area not less than 3 mm longer on the center part side than on the outer edge part side.

### CROSS-REFERENCE TO RELATED APPLICATIONS

This patent application is based upon and claims the benefit of priority of Japanese Patent Application No. 2011-223067, filed on Oct. 7, 2011, the entire contents of which are incorporated herein by reference.

### BACKGROUND OF THE INVENTION

1. Field of the Invention

The present invention relates to a film deposition apparatus and a substrate processing apparatus that perform a film deposition process by supplying plural kinds of process gases onto a substrate in turn.

2. Description of the Related Art

An ALD (Atomic Layer Deposition) method that deposits a reaction product in a layer-by-layer manner on a surface of a substrate such as a semiconductor wafer (which is called a “wafer” hereinafter) by supplying the plural kinds of process gases in turn is taken as one of film deposition methods of depositing a thin film such as a silicon oxide film (SiO₂) and the like on the substrate. As for a film deposition apparatus that performs a film deposition process by using the ALD method, for example, as disclosed in Patent Document 1, an apparatus is known that supports plural wafers arranged on a turntable provided in a vacuum chamber, and for example, supplies respective process gases in turn onto these wafers by rotating the turntable relative to plural gas supplying parts arranged facing the turntable.

In the meanwhile, because a wafer temperature (i.e., a film deposition temperature) in the ALD method is low, for example, about 300° C., compared to an ordinary CVD (Chemical Vapor Deposition) method, for example, an organic substance and the like contained in the process gases may be taken into the thin film as impurities. Accordingly, as disclosed in Patent Document 2, it is conceived that such impurities can be removed or reduced from the thin film by simultaneously performing an alteration process using plasma during a film deposition process.

However, when the plasma is formed above the turntable and the alternation process is performed, speeds of the turntable differ between the center and outer edge sides. More specifically, time periods exposed to the plasma differ between on the center side and on the edge side in a surface of the wafer. As a result, performing a uniform process in the surface of the wafer is difficult, and the uniformity of a film thickness may be decreased. Even though Patent Document 2 discloses a method of improving the uniformity of the film thickness, implementing higher uniformity in the film deposition process is required.
Patent Document 1: Japanese Patent Application Laid-Open Publication No. 2010-239102
Patent Document 2: Japanese Patent Application Laid-Open Publication No. 2011-40574

### SUMMARY OF THE INVENTION

Embodiments of the present invention provide a novel and useful film deposition apparatus and substrate processing apparatus solving one or more of the problems discussed above.

More specifically, embodiments of the present invention provide a film deposition apparatus and a substrate processing apparatus that can perform a uniform process onto a substrate when the substrate passes through plural processing parts in turn so that plural kinds of process gases are supplied and a plasma process is performed onto the substrate.

According to one embodiment of the present invention, there is provided a film deposition apparatus configured to perform a film deposition process on a substrate by rotating a turntable holding the substrate on a substrate mounting area to pass the substrate through plural process areas in turn, thereby performing a cycle of supplying plural kinds of process gases in turn in a vacuum chamber. The film deposition apparatus includes a gas supplying part configured to supply a plasma generating gas on a surface on the substrate mounting area side in the turntable and an antenna configured to convert the plasma generating gas to plasma by induction coupling. The antenna is provided facing the surface of the substrate mounting area side in the turntable so as to extend from a center part to an outer edge part of the turntable. Moreover, the antenna is arranged so as to have a distance from the turntable in the substrate mounting area not less than 3 mm longer on the center part side than on the outer edge part side.

According to another embodiment of the present invention, there is provided a substrate processing apparatus configured to perform a film deposition process on a substrate by rotating a turntable holding the substrate on a substrate mounting area to pass the substrate through plural process areas in turn, thereby performing a cycle of supplying plural kinds of process gases in turn in a vacuum chamber. The substrate processing apparatus includes a gas supplying part configured to supply a plasma generating gas on a surface on the substrate mounting area side in the turntable and an antenna configured to convert the plasma generating gas to plasma by induction coupling. The antenna is provided facing the surface of the substrate mounting area side in the turntable so as to extend from a center part to an outer edge part of the turntable. Furthermore, the antenna is arranged so as to have a distance from the turntable in the substrate mounting area not less than 3 mm longer on the center part side than on the outer edge part side.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a vertical cross-sectional side view showing a film deposition apparatus of a first embodiment of the present invention;

FIG. 2 is an outline cross-sectional perspective view of the film deposition apparatus of the embodiment;

FIG. 3 is a horizontal cross-sectional plan view of the film deposition apparatus of the embodiment;

FIG. 4 is a vertical cross-sectional side view showing a plasma generation part constituting the film deposition apparatus of the embodiment;

FIG. 5 is a vertical cross-sectional front view showing the plasma generation part in the embodiment;

FIG. 6 is an exploded perspective view showing the plasma generation part in the embodiment;

FIG. 7 is an explanation drawing for explaining a positional relationship between a wafer and an antenna;

FIG. 8 is an explanation drawing for explaining a gas flow formed in the film deposition apparatus of the embodiment;

FIG. 9 is a schematic diagram showing plasma generated by the plasma generation part in the embodiment;

FIG. 10 is a side view showing another example of an antenna constituting the film deposition apparatus of the embodiment;

FIG. 11 is a side view showing still another example of an antenna constituting the plasma generation part structure in the embodiment;

FIG. 12 is a perspective view showing a plasma generation part in a second embodiment;

FIG. 13 is a vertical cross-sectional side view showing the plasma generation part in the second embodiment;

FIG. 14 is a vertical cross-sectional side view showing the plasma generation part in the second embodiment;

FIG. 15 is a perspective view showing a plasma generation part in a third embodiment;

FIG. 16 is a vertical cross-sectional side view showing the plasma generation part in the third embodiment;

FIG. 17 is a vertical cross-sectional side view showing the plasma generation part in the third embodiment;

FIG. 18 is a perspective view showing a plasma generation part in a fourth embodiment;

FIG. 19 is a block diagram showing a control part constituting a film deposition apparatus of the fourth embodiment;

FIG. 20 is a side view showing an antenna used in an evaluation test;

FIG. 21 is a side view showing an antenna used in an evaluation test;

FIG. 22 is a side view showing an antenna used in an evaluation test;

FIG. 23 is a top view showing an antenna used in an evaluation test;

FIG. 24 is a top view showing an antenna used in an evaluation test;

FIG. 25 is a graph chart showing a result of the evaluation test;

FIG. 26 is a graph chart showing a result of the evaluation test; and

FIG. 27 is a graph chart showing a result of the evaluation test.

### DETAILED DESCRIPTION OF THE PREFERRED EMBODIMENTS

A description is given below, with reference to drawings of embodiments of the present invention.

### First Embodiment

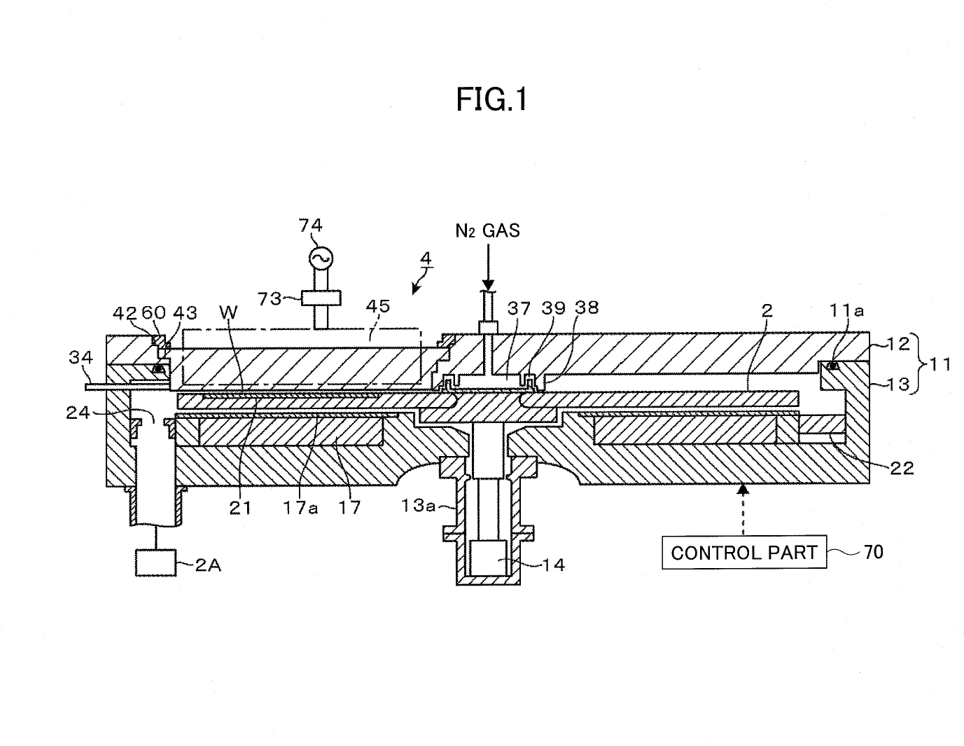

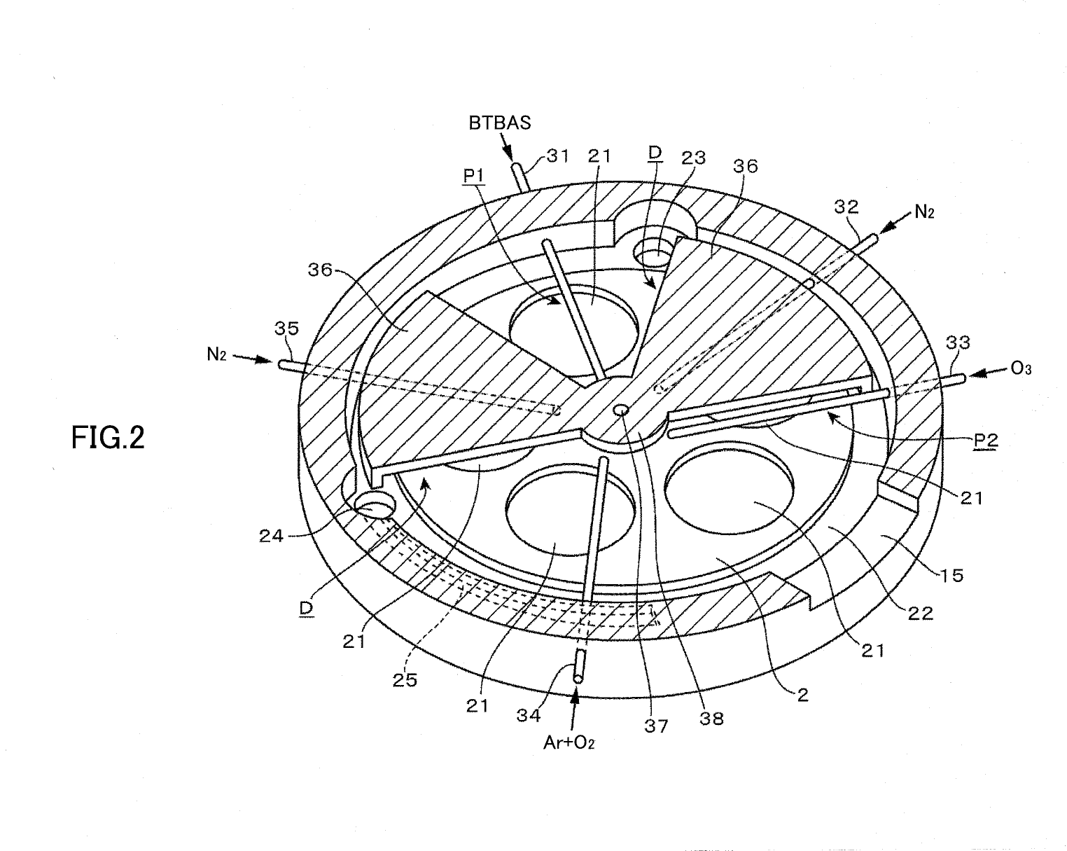

A description is given below about a film deposition apparatus 1 of a first embodiment of the present invention, with reference to FIGS. 1 through 3. FIGS. 1, 2 and 3 are respectively a vertical cross-sectional side view, an outline cross-sectional perspective view, and a horizontal cross-sectional plan view of the film deposition apparatus 1. This film deposition apparatus 1 deposits a thin film on a surface of a wafer W by depositing a reaction product in a layer-by-layer manner by an ALD method, and performs plasma alteration of the thin film. As shown in FIGS. 1 and 2, this film deposition apparatus 1 includes a flat vacuum chamber 11 whose planar shape is an approximately round shape, and a turntable 2 horizontally provided in the vacuum chamber 11. An area surrounding the vacuum chamber 11 is in the atmosphere, and an inner space of the vacuum chamber 11 is made a vacuum during a deposition process. The vacuum chamber 11 is constituted of a ceiling plate 12, and a chamber body 13 that forms a side wall and a bottom part of the vacuum chamber 11. In FIG. 1, a sealing member 11a is provided between the ceiling plate 12 and the chamber body 13 to keep the inside of the vacuum chamber 11 hermetic, and a cover 13a is provided to close the center of the chamber body 13.

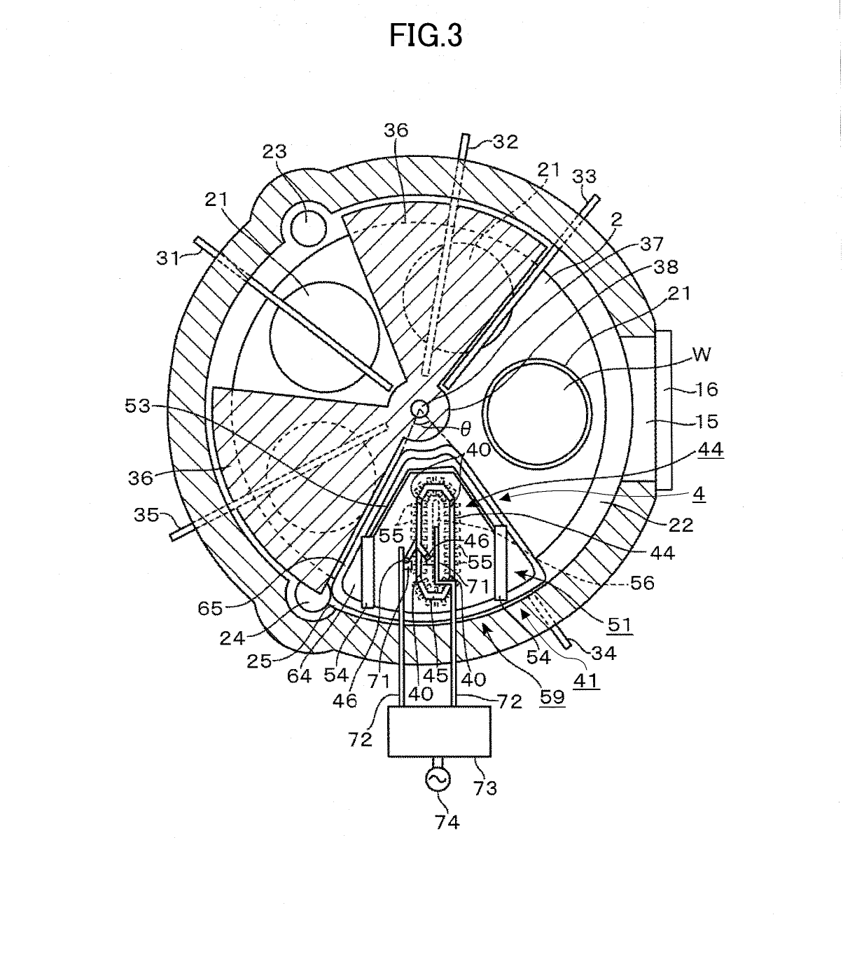

The turntable 2 is connected to a rotary drive mechanism 14, and rotates around the central axis thereof in a circumferential direction by the rotary drive mechanism 14. As shown in FIG. 2, five concave portions 21 of substrate mounting areas are formed along the circumferential direction on a surface (one surface) of the turntable 2, and a wafer W of a substrate is loaded on the concave portion 21. Then, the wafer W on the concave portion 21 rotates around the central axis by rotation of the turntable 2. As shown in FIG. 2, a transfer opening 15 of the wafer W is provided. Also, as shown in FIG. 3, a shutter 16 capable of opening and closing the transfer opening 15 (which is omitted in FIG. 2) is provided. In the bottom surfaces of the concave portions 21, three holes not shown in the drawings are formed in a thickness direction of the turntable 2, and not shown three lift pins movable upward and downward through the respective three holes protrude from or go below the surface of the turntable 2, by which the wafer W is transferred between a transfer mechanism of the wafer W and the concave portion 21.

As shown in FIGS. 2 and 3, a first process nozzle 31, a separation nozzle 32, a second process gas nozzle 33, a plasma generating gas nozzle 34, and a separation gas nozzle 35 that extend from an outer edge toward the center of the turntable 2 are provided in a clockwise fashion in this order above the turntable 2. Many discharge ports are formed in the lower surface of the gas nozzles 31 through 35 along respective nozzle length directions.

The first process gas nozzle 31 discharges a BTBAS (bistertiary-butylaminosilane: SiH₂ (NH—C(CH₃)₃)₂) gas containing Si (silicon), and the second process gas nozzle 33 discharges an O₃ (ozone) gas. The plasma generating gas nozzle 34 discharges, for example, a mixed gas of an Ar (argon) gas and an O₂ gas (volume ratio is about Ar:O₂=100:0.5 to 100:20). The separation gas nozzles 32, 35 discharge N₂ (nitrogen) gases.

As shown in FIGS. 1 and 2, the ceiling plate 12 of the vacuum chamber 11 includes two sectorial protrusion parts 36 protruding downward, and the protrusion parts 36 are formed at some interval. The respective separation gas nozzles 32, 35 are housed in corresponding groove portions (not shown) that are provided in the corresponding protrusion parts 36 thereby to divide the protrusion parts 36 in the circumferential direction. The first process gas nozzle 31 and the second process gas nozzle 32 are provided away from the respective protrusion parts 36.

In FIG. 2, an area below the first process gas nozzle 31 forms a first process area P1 to adsorb the Si containing gas on the wafer W, and an area below the second process gas nozzle 32 forms a second process area P2 to react the Si containing gas adsorbed on the wafer W with the O₃ gas. Areas below the protrusion parts 36 are formed as separation areas D, D. The N₂ gases supplied from the separation gas nozzles 32, 35 to the separation areas D spread under the separation areas D in the circumferential direction during the film deposition process, prevent the BTBAS gas and the O₃ gas from being mixed above the turntable 2, and sweep away these gases to evacuation ports 23, 24 described below.

As shown in FIGS. 1 through 3, a ring member 22 is provided outside and below the turntable 2, and protects an inner wall of the vacuum chamber 11 from a fluorine system cleaning gas when the fluorine system cleaning gas is circulated in the vacuum chamber 11. The evacuation ports 23, 24 are opened in the upper surface of the ring member 22, and the evacuation ports 23, 24 are respectively connected to a vacuum evacuation unit 2A such as a vacuum pump. The evacuation port 23 exhausts the BTBAS gas from the first process gas nozzle 31, and the evacuation port 24 exhausts the O₃ gas supplied from the second process gas nozzle 33 and the mixed gas supplied from the plasma generating gas nozzle 34. Moreover, the N₂ gases supplied from the separation gas nozzles 32, 35 are exhausted from the respective evacuation ports 23, 24. As shown in FIG. 2, a groove part 25 is provided in the upper surface of the ring member 22, and guides the above respective gases that flow toward the evacuation port 24.

As shown in FIG. 1, an N₂ gas is supplied to a center area 37 of the turntable 2, and supplied outward in a radial direction of the turntable 2 through a flow passage 39 formed in a protrusion portion 38 protruding downward in a circle, in the ceiling plate 12, which prevents the respective gases from being mixed in the center area 37. As shown in FIGS. 2 and 3, the inner edges of the protrusion parts 36, 36 are connected to the outer edge of the protrusion portion 39. Furthermore, though the drawing is omitted, the N₂ gas is also supplied to the inside of the cover 13a and the back surface of the turntable 2, and the process gas is purged.

As shown in FIG. 1, a heater 17 is provided on the bottom part of the vacuum chamber 11, that is to say, below and away from the turntable 2. A temperature of the turntable 2 is increased by radiation heat to the turntable 2 of the heater 17, and the wafer W loaded on the concave portion 21 is heated. As shown in FIG. 1, a shield 17a is provided to prevent a film from being deposited on a surface of the heater 17.

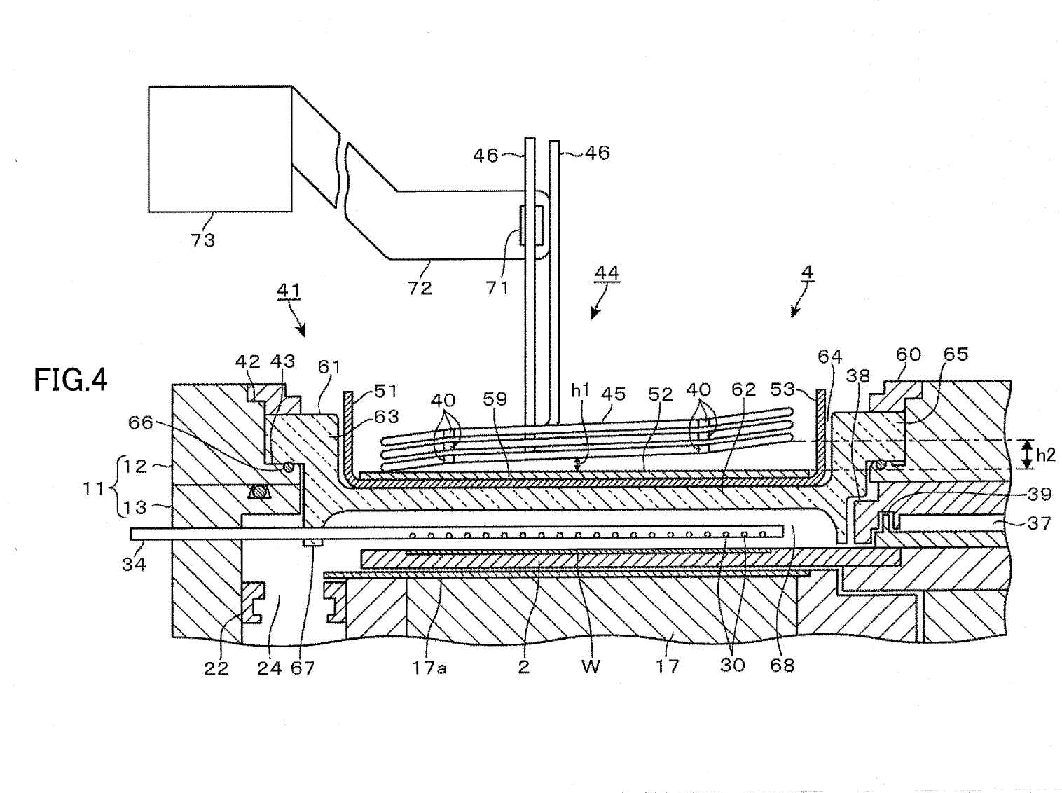

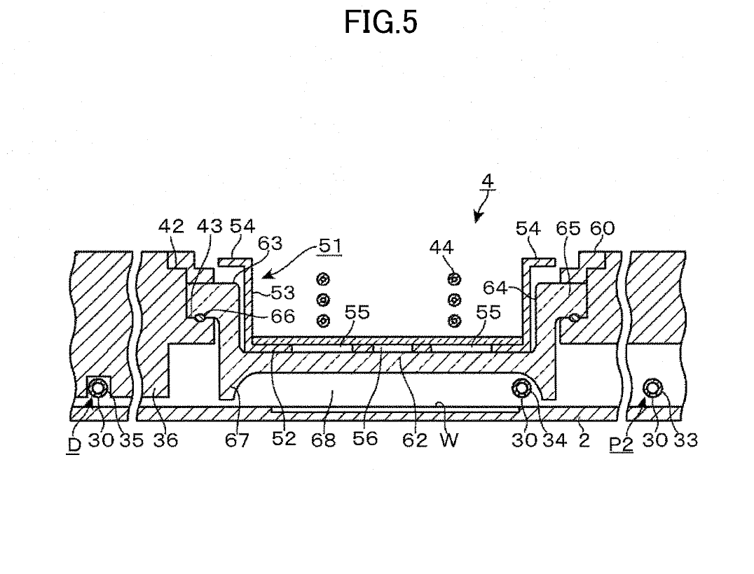

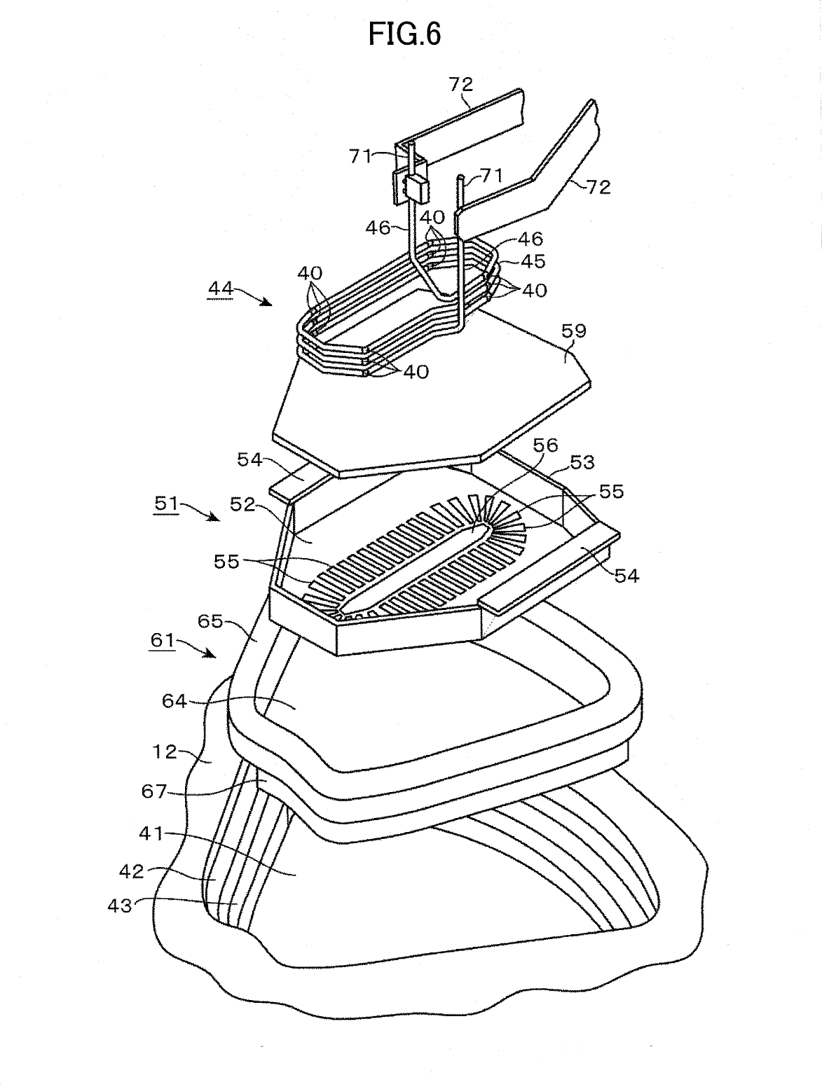

Next, a description is given about a plasma generating part 4, also referring to FIGS. 4 though 6. FIG. 4 is a vertical cross-sectional side view of the plasma generating part 4 as seen along the radial direction of the turntable 2. FIG. 5 is a vertical cross-sectional front view of the plasma generating part 4 as seen from the rotation center of the turntable 2. FIG. 6 is an exploded perspective view of respective parts of the plasma generating part 4.

The plasma generating part 4 is provided in an opening part 41 passing through in a thickness direction of the ceiling plate 12. The opening part 41 is formed in an area above the plasma generating gas nozzle 34 discussed above. More specifically, as shown in FIG. 3, the plasma generating part 4 is formed from a position on the slightly upstream side of the plasma generating gas nozzle 34 in the rotational direction of the turntable 2 to a position slightly closer to the plasma generating gas nozzle 34 than the separation area D on the downstream side of the plasma generating gas nozzle 34 in the rotational direction. The opening part 41 is formed into an approximate sector shape as seen from a planar perspective, and is formed from a position slightly outer than the rotation center of the turntable 2 across to a position outer than the outer edge of the turntable 2. As shown in FIG. 4, for example, step parts 42, 43 are vertically formed across the circumferential direction so that an opening diameter of the opening part 41 decreases in stages from the top end to the bottom end.

The plasma generating part 4 includes an antenna 44, a Faraday shield 51, an insulating member 59, and a casing 61 forming a discharge part. The casing 61 is a permeable material (i.e., a substance that allows a magnetic field to pass through) made of a dielectric material such as quartz, and is formed to be an approximate sector as seen from a planar perspective so as to fill the opening part 41. For example, an angle formed by an outline of the sector shown in FIG. 3 is 68 degrees. The casing 61 includes a sectorial horizontal plate 62 having a thickness, for example, of 20 mm. A periphery of the horizontal plate 62 protrudes upward to form a side wall 63, and the side wall 63 and the horizontal plate 62 form a concave part 64. When the casing 61 is dropped into the opening part 41, a flange part 65 and the step part 43 on the lower side engage with each other. As shown in FIG. 4, an O-ring 66 to seal the flange part 65 and the step part 43 is provided. Moreover, a ring member 60 is provided on the flange part 65, and is engaged with the step part 42 on the upper side. The ring member 60 presses the flange part 65 to the O-ring 66, and keeps the inside of the vacuum chamber 11 hermetic.

A projection part 67 is formed along the periphery and in the bottom part of the horizontal plate 62. This projection part 67 prevents the N₂ gases and the O₃ gas from entering a plasma formation area (i.e., discharge area) 68 surrounded by the projection part 67, the horizontal plate 62 and the turntable 2, and prevents a NOₓ gas from being generated by allowing the plasma of these gases to react with each other. Furthermore, the projection part 67 functions to lengthen a distance before the plasma generated in the plasma formation area 68 reaches the O-ring 66, and to facilitate to deactivate the plasma before reaching the sealing member 66.

The plasma generating gas nozzle 34 enters the plasma formation area 68 through a cutout provided in the projection part 67. The discharge ports 30 of the plasma generating gas nozzle 34 are open facing obliquely downward and toward the upstream side in the rotational direction of the turntable 2 so as to prevent the O₃ gas and the N₂ gas that flow from the upstream side in the rotational direction from entering the plasma formation area 68. The discharge ports 30 of the other gas nozzles are opened facing vertically downward. The plasma generating gas is suctioned by the evacuation port 24, and exhausted to the outside of the plasma formation area 68 from the outer edge side and the downstream side in the rotational direction.

A height from the surface of the turntable 2 and the wafer W to a ceiling part (i.e., the horizontal plate 62) of the plasma formation area 68 is, for example, 4 to 60 mm, and 30 mm in this example. A distance between the lower end of the projection part 67 and the upper surface of the turntable 2 is 0.5 to 4 mm, and 2 mm in this example. The width dimension and the height dimension of this projection part 67 are respectively 10 mm and 28 mm.

The Faraday shield 51 of an electric field shield member is provided in the concave part 64 of the casing 61. The Faraday shield 51 is made of a metal plate (e.g., a copper (Cu) plate or a plate material of a copper plate plated with a nickel (Ni) film and a gold (Au) film). The Faraday shield 51 includes a bottom plate 52 stacked on the horizontal plate 62 of the concave part 64, and a vertical plate 53 extending upward from the outer edge of the bottom plate 52 across in the circumferential direction, and is formed to be a box shape whose top is open. In addition, as shown in FIGS. 5 and 6, when the Faraday shield 51 is seen from the rotation center toward the outer edge, brim plates 54, 54 that respectively extend rightward and leftward from the Faraday shield 51 are provided, and the respective brim plates 54 are provided at the upper end of the vertical plate 53. The respective brim plates 54 are connected to a (not shown) conductive member provided at the edge of the ceiling plate 12, and the Faraday shield 51 is grounded through this conductive member. The thickness of respective parts of the Faraday shield 51 is, for example, 1 mm.

As shown in FIG. 6, many slits 55 are provided in the bottom plate 52 of the Faraday shield 51. The respective slits 55 extend so as to be perpendicular to an extending direction of a metal wire that forms an antenna and is wound around in a coil form, and are arranged at intervals along the extending direction of the metal wire and thus in substantially an octagonal top-view shape drawn-out in the radial direction of the turntable 2. The respective drawings show the slits 55 in a simplified depiction, but in actually 150 or more slits 55 can be formed. A width dimension of the slits 55 is 1 to 5 mm, for example about 2 mm, and a distance between the slits 55, 55 is 1 to 5 mm, for example about 2 mm. An opening part 56 is formed in the bottom plate 52 of the octagonal shape as enclosed by the slits 55. A distance between the opening part 56 and the slits 55 is, for example, 2 mm.

The Faraday shield 51 prevents an electric field component of the electromagnetic field, which is generated around the antenna 44 to which a radio frequency is applied, from going downward to the wafer W, thereby preventing electric interconnections formed inside the wafer W from being damaged electrically. On the other hand, the Faraday shield 51 serves to form plasma in the plasma formation area 68 by allowing the magnetic field to pass downward through the slits 55. In addition, the opening part 56 functions to pass the magnetic field through as well as the slits 55.

The plate-like insulating member 59 is stacked on the bottom plate 52 of the Faraday shield 52 to cover the bottom plate 52. The insulating member 59 is provided to isolate the antenna 44 from the Faraday shield 51, and for example, is made of quartz. The thickness of the insulating member 59 is, for example, about 2 mm. The insulating member 59 is not limited to be formed in a plate-like shape, but may be formed into a box shape whose top is open.

Next, a description is given about the antenna 44. For example, the antenna 44 is made of a hollow metal wire formed by plating a surface of copper with nickel and gold in this order. The antenna 44 is configured to include a coil-type electrode 45 that is vertically stacked by winding around triply, and both ends of the coil-type electrodes 45 are pulled upward. The pulled up parts are expressed as supported end parts 46, 46. Cooled water for cooling the metal wire circulates through an inner space of the metal wire by a (not shown) circulation mechanism, by which heat radiation in applying the radio frequency is suppressed.

The supported end parts 46, 46 are, for example, respectively supported by being fixed to first ends of bus bars 72, 72 though rectangular connection members 71, 71. The other ends of the respective bus bars 72, 72 extend on the ceiling plate 12 outward from the ceiling plate 12, and are connected to a radio frequency power source 74 of a frequency, for example, of 13.56 MHz through a matching box 73. The bus bar 72 and connection member 71 form a conducting path, and can supply radio frequency power from the radio frequency power source 74 to the coil-type electrode 45. With this, an induction electric field and an induction magnetic field are formed around the coil-type electrode 45 as discussed above, which causes induction coupled plasma to be formed in the plasma formation area 68, and the plasma formation area 68 enters a discharge state.

The coil-type electrode 45 of the antenna 44 is provided on the insulating member 59, and is surrounded by the vertical plate 53 of the Faraday shield 51. A further description is given about a configuration of the coil-type electrode 45. The coil-type electrode 45 is wound around in an approximate octagonal shape and drawn out in a radial direction of the turntable 2 as seen from a planar perspective. The corner part of the octagonal shape couples linear parts to each other, and forms a bended joint part 40.

The coil-type electrode 45 is provided facing the rotation table through the casing 61, the Faraday shield 51 and the insulating member 59. As shown in FIG. 4, the coil-type electrode 45 is formed from the edge on the rotation center side to the outer edge of the turntable 2.

This causes the plasma to form under the coil-type electrode 45, and allows the entire wafer W to be processed by the plasma.

As discussed above, when the turntable 2 rotates, because the circumferential speed becomes faster on the outer edge side than on the rotation center side, the outer edge side in the surface of the wafer W is exposed by the plasma for a shorter period than the rotation center side. Therefore, as shown in FIG. 4, the coil-type electrode 45 of the antenna 44 is bent at the joint part 40 as seen from a side, and is formed in a mountain-like shape that is higher on the rotation center side than on the outer edge side, so that the coil-type electrode 45 is configured to increase a distance from the turntable 2 with increasing distance from the outer edge side toward the rotation center side. In other words, the rotation center side of the coil-type electrode 45 has a longer distance to the wafer W than the outer edge side, and has attenuation of the magnetic component until reaching the wafer W greater than the outer edge side. Accordingly, in the plasma formation area 68, intensity of the plasma becomes weaker on the rotation center side than on the outer edge side.

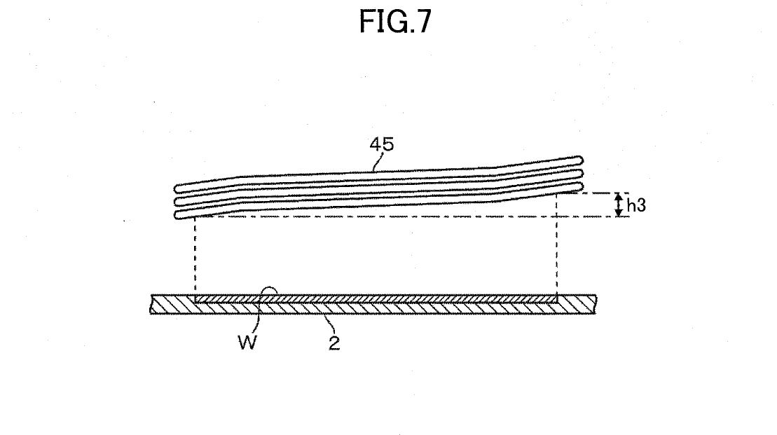

In FIG. 4, a height from the midportion between the rotation center and the outer edge part on the surface of the insulating member 59 to the coil-type electrode 45 is made h1, and 2 to 10 mm in this example. Also, a height from the surface of the insulating member 59 to the end of the coil-type electrode 45 on the rotation center side is made h2, and 4 to 15 mm in this example. The height positions of respective parts of the antenna 44 are not limited to this example. FIG. 7 shows a positional relationship between the wafer W and the coil-type electrode 45 when the coil-type electrode 45 is seen from a side. In FIG. 7, in the concave portion 21 of the substrate mounting area, that is to say, in the wafer W, a difference of distances from the end on the rotation center side of the turntable 2 to the coil-type electrode 45, and from the outer edge side to the coil-type electrode 45 is made h3. By forming the coil-type electrode 45 so that the h3 is 3 mm or more, a distribution of the plasma intensity can be controlled as mentioned above, and the plasma process can be performed onto the surface of the wafer W with a high degree of uniformity.

Moreover, a control part 70 constituted of a computer to control operation of the whole apparatus is provided in this film deposition apparatus, and a program to implement a film deposition process and an alteration process that are described below is stored in a memory of the control part 70. This program is constituted of instructions of step groups to cause the apparatus to implement operations described below, and is installed from a memory unit 121 to be a storage medium such as a hard disk, a compact disc, a magnetic optical disc, a memory card and a flexible disc into the control part 120.

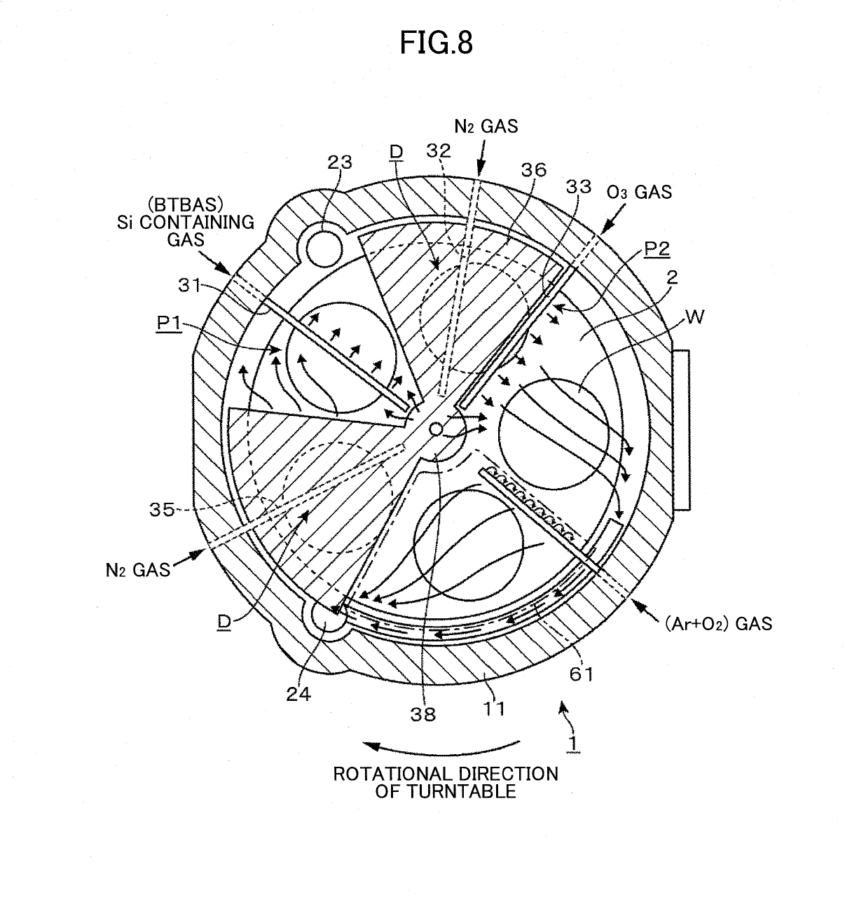

Next, a description is given about operation of the above-mentioned embodiment, referring to FIG. 8 showing flows of respective gases. To begin with, in a state of the shutter 16 being open, while rotating the turntable 2 intermittently, for example, five wafers W are loaded on the turntable 2 through the transfer opening 15 by a not shown transfer arm. Next, the shutter 16 is closed; the inside of the vacuum chamber 11 is kept being evacuated by the vacuum evacuation unit 2A; and the wafer W is heated by the heater unit 7, for example, to 300° C., while rotating the turntable 2 at 120 rpm in a clockwise fashion.

Subsequently, the process gas nozzles 31, 33 respectively discharge a Si-containing gas and an O₃ gas, and the plasma generating gas nozzle 34 discharges a mixed gas of an Ar gas and an O₂ gas, for example, at 5 slm. Furthermore, separation gas nozzles 32, 35 and the protrusion part 39 respectively discharge N₂ gases at predetermined flow rates. Then, the vacuum evacuation unit 2A adjusts a pressure in the vacuum chamber 11 at a preliminarily set processing pressure, for example, at 133 Pa. In addition, radio frequency power, for example, of 1500 W is supplied to the antenna 44.

The plasma generating gas discharged from the plasma generating gas nozzle 34 collides with the lower side of the projection part 67 of the casing 61, and throws out the O₃ gas or N₂ gas attempting to flow into the plasma formation area 68 below the casing 61. Then, the plasma generating gas is pushed back toward the downstream side in the rotational direction of the turntable 2 by the projection part 67. At this time, by setting gas flow rates at the above-stated respective gas flow rates and by providing the projection part 67, for example, a pressure of the plasma formation area 68 becomes about 10 Pa higher than that of the other area, by which intrusion of the O₃ gas or the N₂ gas toward the plasma formation area 68 is also prevented. Furthermore, the plasma formation area 68 that has the higher pressure than the other areas also prevents the N₂ gas supplied from the protrusion portion 38 from intruding, and forces the N₂ gas to flow toward the periphery of the turntable 2 so as to flow around the plasma formation area 68. In addition, as shown in FIG. 8, because the N₂ gas is supplied to the separation area D between the first process area P1 and the second process area P2, the Si containing gas, the O₃ gas and the plasma generating gas are evacuated not to be mixed with each other.

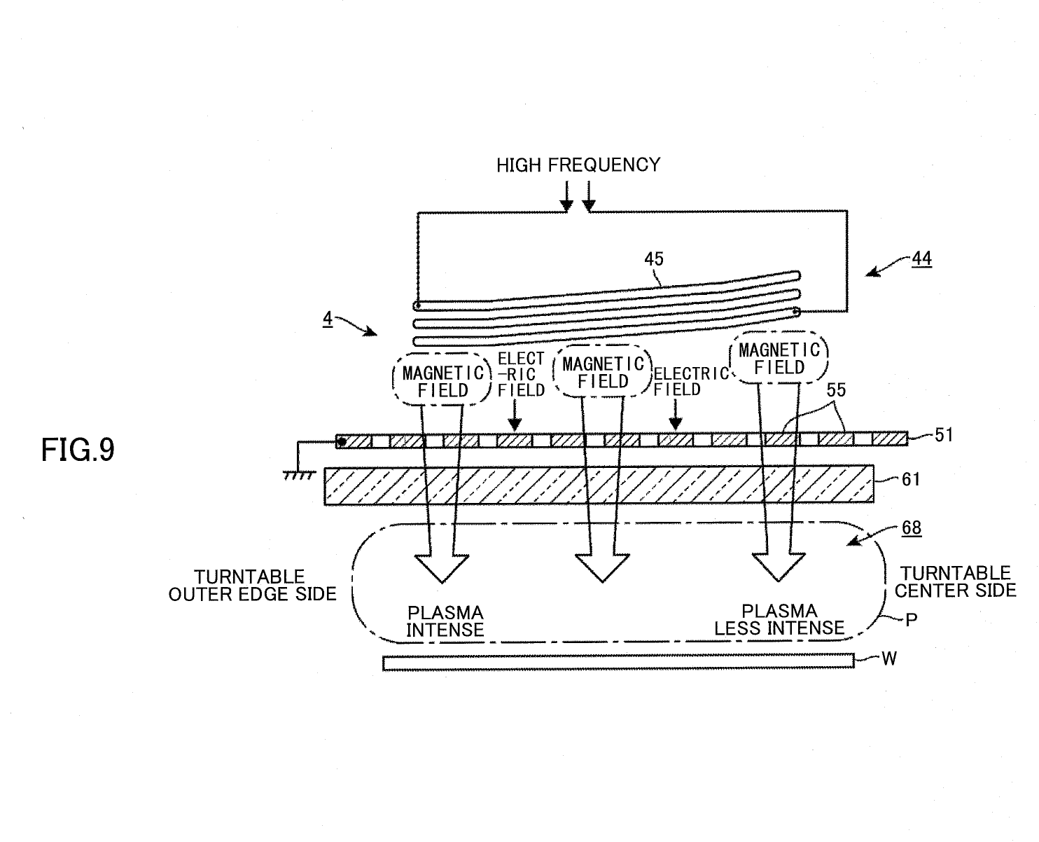

The wafer W reaches the first process area P1 by the rotation of the turntable 2 and the Si-containing gas is adsorbed on the surface of the wafer W in the first process area P1. Next, the Si-containing gas having been adsorbed on the surface of the wafer W is oxidized by the O₃ gas in the second process area P2, and one or more molecular layers of a silicon oxide film (SiO₂) to be a film component are deposited. Next, a description is further given, with reference to FIG. 9 showing the plasma generating part 4 schematically. An electric field and a magnetic field occur around the coil-type electrode 45 of the antenna 44 due to the radio frequency power supplied from the radio frequency power source 74. As discussed above, the generated electric field is inhibited (blocked) from reaching the plasma formation area 68 by being reflected or absorbed (diminished) by the Faraday shield 51. On the other hand, the magnetic field transmits through the slits 55 and the casing 61 of the Faraday shield 51, and activates the plasma generating gas by being supplied onto the turntable 2, by which plasma P such as ions or radicals is generated.

As discussed above, because the coil-type electrode 45 of the antenna 44 is configured to increase the distance from the turntable 2 with increasing distance from the outer edge side toward the rotation center side, the attenuation of the magnetic field until reaching the turntable 2 increases as approaching the rotation center side. Accordingly, the intensity of the plasma P generated on the surface of the turntable 2 decreases with increasing distance from the outer edge side toward the center side. As a result, the wafer W passes an atmosphere of high plasma intensity at a relatively high speed as approaching the outer edge side, and an atmosphere of low plasma intensity at a relatively low speed as approaching the center side.

Then, the plasma P formed in this manner serves to alter the silicon oxide film formed on the surface of the wafer W. More specifically, impurities such as an organic substance are released from the silicon oxide film, or densification (an increase in the density) of the silicon oxide film is achieved by causing an element in the silicon oxide film to be rearranged. Moreover, an OH group to be an adsorb site of the Si containing gas is formed with a high degree of uniformity on a surface of the silicon oxide film, and oxidation of the Si (silicon) constituting the surface of the wafer W is developed with a high degree of uniformity.

By continuing the rotation of the turntable 2, the adsorption of the Si containing gas, the oxidation of the surface of the wafer by the O₃ gas, and the alteration of the silicon oxide by the plasma P are repeated in turn onto the respective wafers W, and the SiO₂ molecules are deposited on the wafers W in a layer-by-layer manner. When the SiO₂ film with a predetermined film thickness is deposited, supply of the respective gases is stopped, and the wafer W is carried out of the film deposition apparatus in reverse operation to that in carrying in the wafer W.

In the film deposition apparatus 1, the antenna 44 constituted of the bent coil-type electrode 45 as seen from a side perspective is provided. When the turntable 2 rotates, because the outer edge side rotates at faster circumferential speed than the rotation center side, the outer edge side is exposed by the plasma P of the plasma formation area 68 for a shorter period. However, by configuring the antenna 44 as discussed above, and by suppressing the plasma intensity on the rotation center side more than on the outer edge side, a high uniformity plasma process can be performed onto the surface of the wafer W, and the SiO₂ film of high uniformity can be deposited on the wafer W.

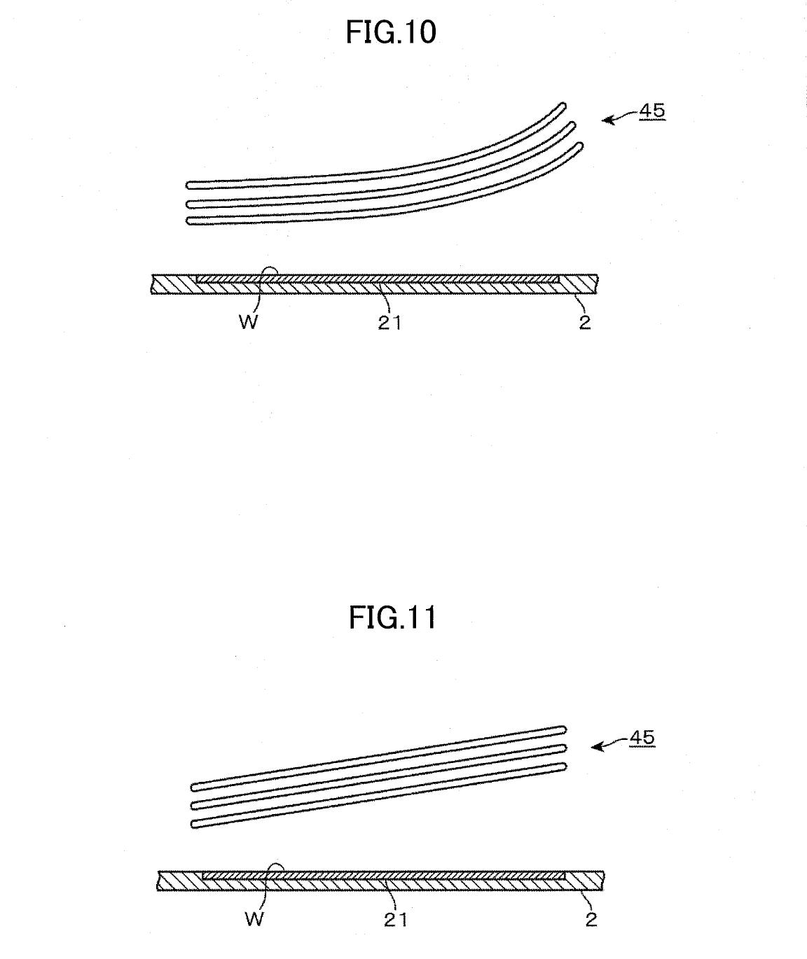

As shown in FIG. 10, the coil-type electrode 45 of the antenna 44 may be formed to curve in an arc-like shape as seen from a side, and to become higher on the rotation center side than on the outer edge side of the turntable 2. As shown in FIG. 11, the coil-type electrode 45 may be formed to extend a metal wire linearly as seen from the side. Even when the coil-type electrode 45 is formed in such ways, the coil-type electrode 45 is set to be more distant from the wafer W on the rotation center side than on the outer edge side.

### Second Embodiment

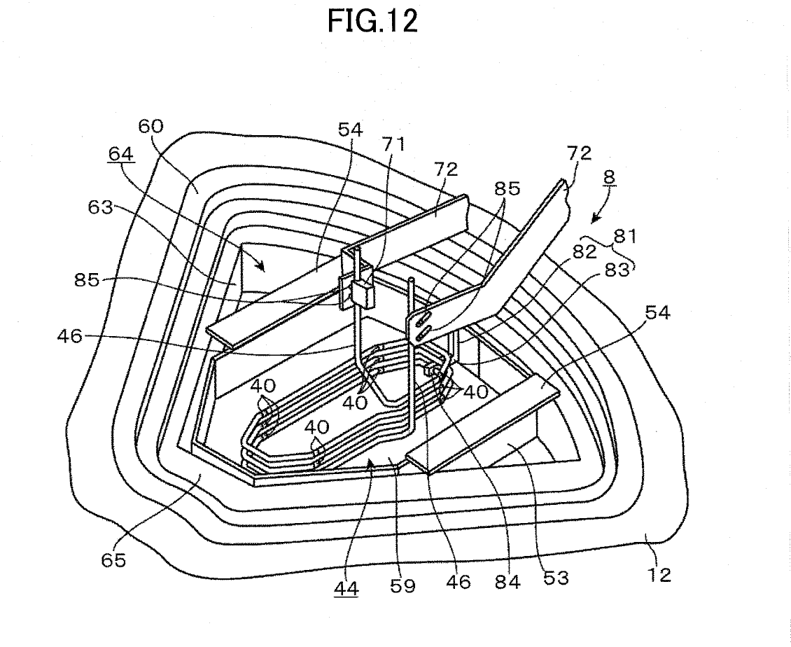

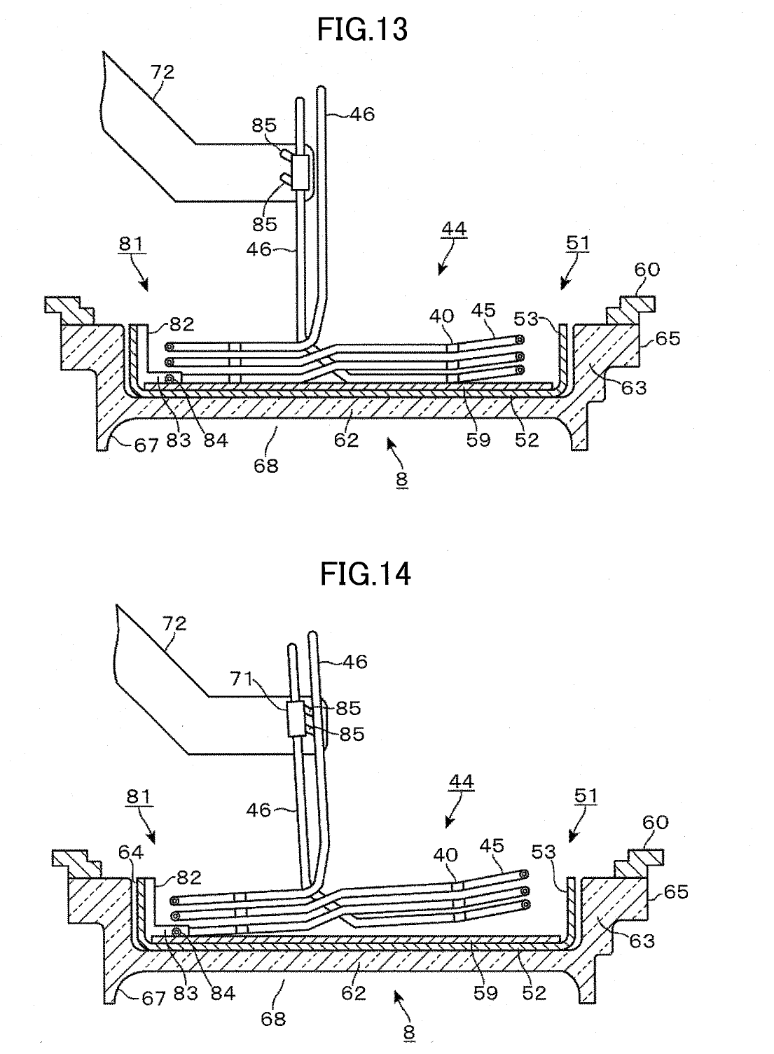

Subsequently, a description is given about a second embodiment, with a focus on different points from the first embodiment. FIG. 12 is a perspective view of a plasma generating part 8 of the second embodiment, and FIGS. 13 and 14 are side views of this plasma generating part 8. This plasma generating part 8 includes an L-shaped angle adjustment member 81 as seen from a side provided on an insulating member 59 on the outer edge side of the turntable 2, and a vertical part 82 of the L-shape is fixed to a vertical plate 53 of the Faraday shield 51. A cutout 84 is formed on the lower side of a horizontal part 83, and the lowest metal wire on the outer edge side of the coil-type electrode 45 passes through the cutout 84 to be sandwiched between the insulating member 59 and the horizontal part 83. Then, as shown in FIGS. 13 and 14, an antenna 44 is configured to be rotatable around the metal wire passing through the cutout 84. This rotational axis is a horizontal axis perpendicular to a radial direction of the turntable 2.

Slits 85 are formed in respective bus bars 72, and a connection member 71 includes pins 86 corresponding to these slits 85. The pins 86 can be fixed at any positions of the slits 85, and thereby fix the coil-type electrode 45 at any angle positions relative to the horizontal plane so that a height thereof is higher on the center side of the turntable 2 than on the outer edge side. Furthermore, the angle can be changed, for example, by one degree units. In other words, the angle adjustment member 81 serves as an angle adjustment mechanism that adjusts an angle of the antenna 44 in the vertical direction through the bus bar 72 to be a support part.

In this case also, the difference 3h between distances from the rotation center side in the wafer W to the antenna 44 and from the outer edge side in the wafer W to the antenna 44 is set in the above-discussed range. Moreover, within the range, a user can change the angle of the coil-type electrode 45 in accordance with a process performed on the wafer W, for example, a film thickness deposited on the wafer W or a rotational speed of the turntable 2. Then, plasma distribution in a radial direction of the wafer W along the radial direction of the turntable 2 can be proper, and a uniform process can be performed on a surface of the wafer W.

### Third Embodiment

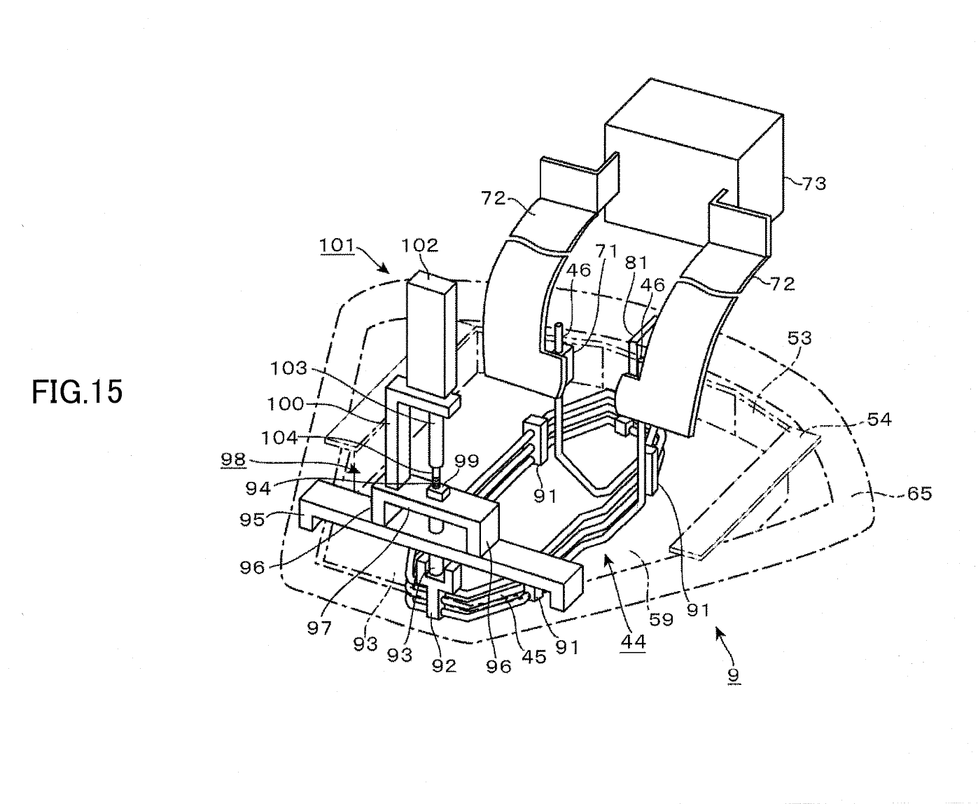

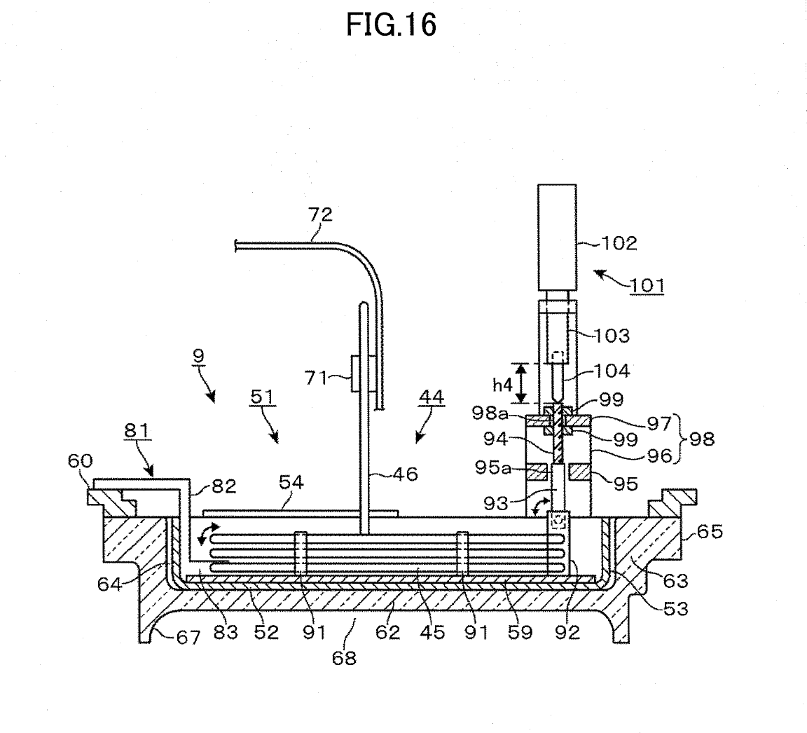

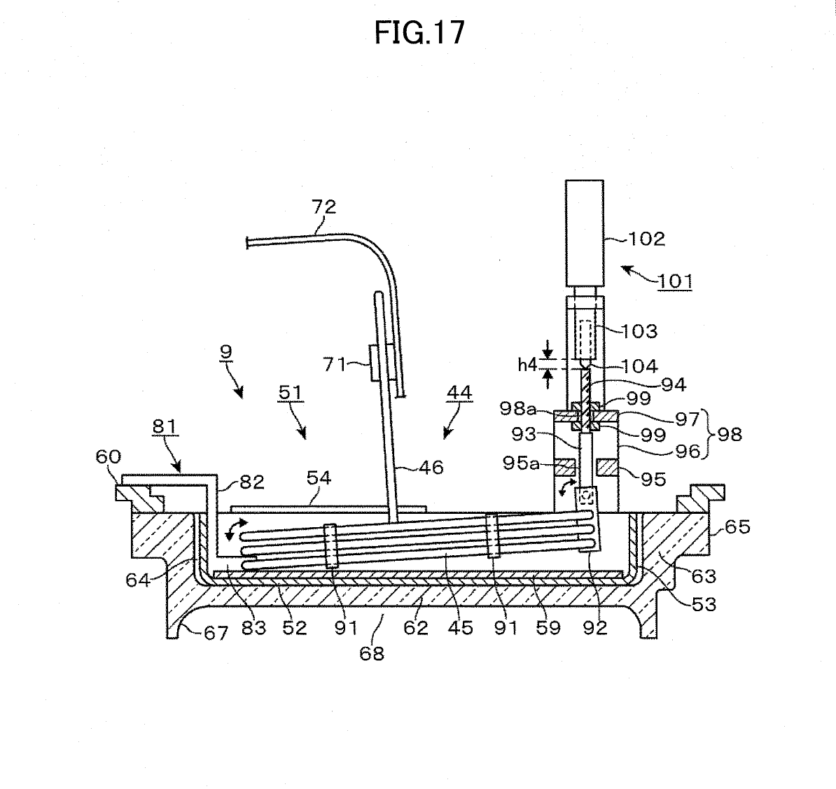

A plasma generating part 9 of a third embodiment adjusts an angle in the vertical direction of an antenna similarly to the second embodiment. FIG. 15 is a perspective view of the plasma generating part 9, and FIGS. 16 and 17 are side views of the plasma generating part 9. This antenna 44 includes four distance adjustment members 91 and lifting members 92 formed as blocks respectively. The distance adjustment members 91 and the lifting members 92 have three holes provided at intervals in the vertical direction, and a metal wire configuring the antenna 44 forms the coil-type electrode 45 by being inserted to the holes and wound around, which prevents the metal wire of the respective stages from contacting each other in changing the angle of the antenna 44. This distance adjustment member 91 may be used for an antenna 44 in other embodiments.

The Faraday shield 51 includes an angle adjustment member 81 similarly to the second embodiment, and the antenna 44 is configured to allow the angle to be adjustable. The lifting member 92 is arranged at the center side of the turntable 2 of the coil-type electrode 45, and a rod 93 extending upward is connected to the upper side of the lifting member 92. The rod 93 is configured to be rotatable around an axis parallel to the rotational axis of the antenna 44 relative to the lifting member 92, and a pressure applied to the antenna 44 can be inhibited when the angle of the antenna 44 is changed. A long screw 94 is provided so as to extend from the end of the rod 93 in a length direction of the rod 93.

A bridge-like member 95 is provided so as to bridge between the upstream side and the downstream side in the rotational direction of a flange part 65 of the casing 61 (see FIG. 6), and the bridge-like member 95 is fixed to the casing 61. A supporting rack 98 including a pair of leg parts 96 extending in the vertical direction, and a horizontal part 97 connecting top ends of the leg parts 96 to each other is provided on the bridge-like member 95. Through-holes 95a, 98a are respectively provided in the bridge-like member 95 and the horizontal part 97 of the supporting rack 98 in the vertical direction, and the respective through-holes 95a, 98a are arranged to overlap with each other. The rods 93 and the long screw 94 respectively pass through the through-holes 95a, 98a. Also, nuts 99, 99 are provided to fix the long screw 94 to the horizontal part 97.

As shown in FIGS. 16 and 17, the long screw 94 can be attached to the horizontal part 97 at any heights by nuts 99. In accordance with the attached position, the rotation center side of the coil-type electrode 45 is raised, so that the height difference h3, in other words, an angle of the antenna 44 relative to the horizontal plane, is adjustable. Furthermore, the bus bars 72 are made of a thin plate with flexibility to change the angle arbitrarily as mentioned above.

A linear gauge 101 is provided above the horizontal part 97, and is supported by the supporting member 100. The linear gauge 101 includes a measurement body part 102, a cylindrical part 103 extending from the measurement body part 102 in the vertical direction, and a vertically moving shaft 104 extending from the cylindrical part 103 in the vertical direction. The vertically moving shaft 104 is configured to be movable in the vertical direction relative to cylindrical part 103, and an end of the vertically moving shaft 104 contacts an end of the long screw 94. In addition, the measurement body part 102 is connected to a display part not shown in the drawing, and is configured to measure a distance h4 between the end position of the lofting shaft 104 and a predetermined height position of the cylindrical part 103, for example, the end position of the cylindrical part 103, and to display the distance h4 on the display.

An intended film thickness of the SiO₂ film and a proper distance h4 for each rotational speed of the turntable 2 are preliminarily obtained. Then, the distance (height) h4 is changed so as to be the proper value in accordance with the process conditions before starting the above film deposition process. By doing this, a high uniformity deposition process can be carried out on the surface of the wafer W.

### Fourth Embodiment

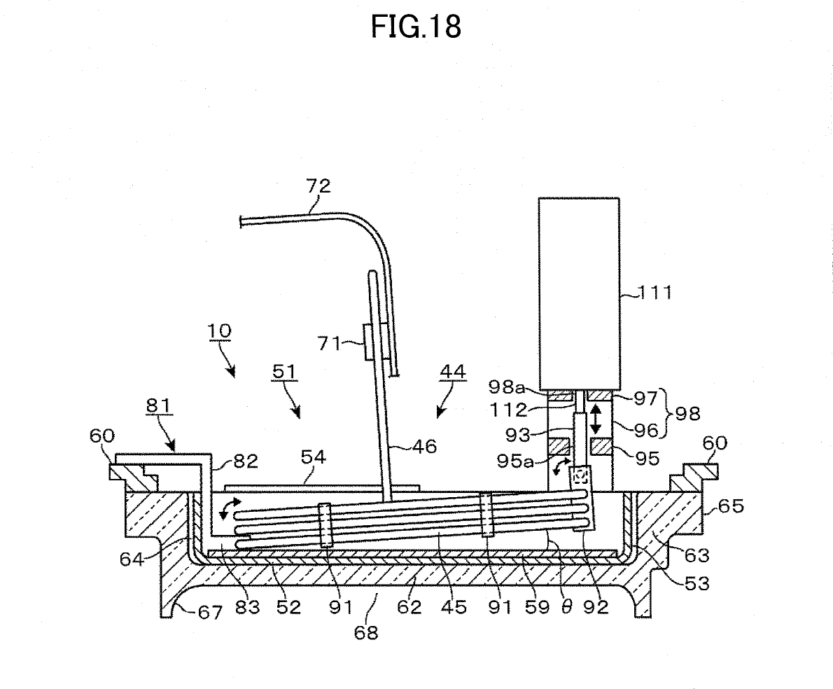

A description is given about a configuration of a plasma generating part 10 of a fourth embodiment with a focus on different points from the third embodiment, referring to FIG. 18. A drive mechanism 111 is provided on a horizontal part 97 of this plasma generating part 10. The drive mechanism 111 raises and lowers a vertically moving shaft 112 extending downward. The lower end of the vertically moving shaft 112 is connected to a rod 93, and an angle relative to a horizontal plane of the antenna 44 is changeable in accordance with moving up and down of the rod 93. The lowest height of the vertically moving shaft 112 is controlled by a control part 70, by which an inclination of the antenna 44 relative to the horizontal plane shown in the drawing as 81 is controlled by a control signal transmitted from the control part 70.

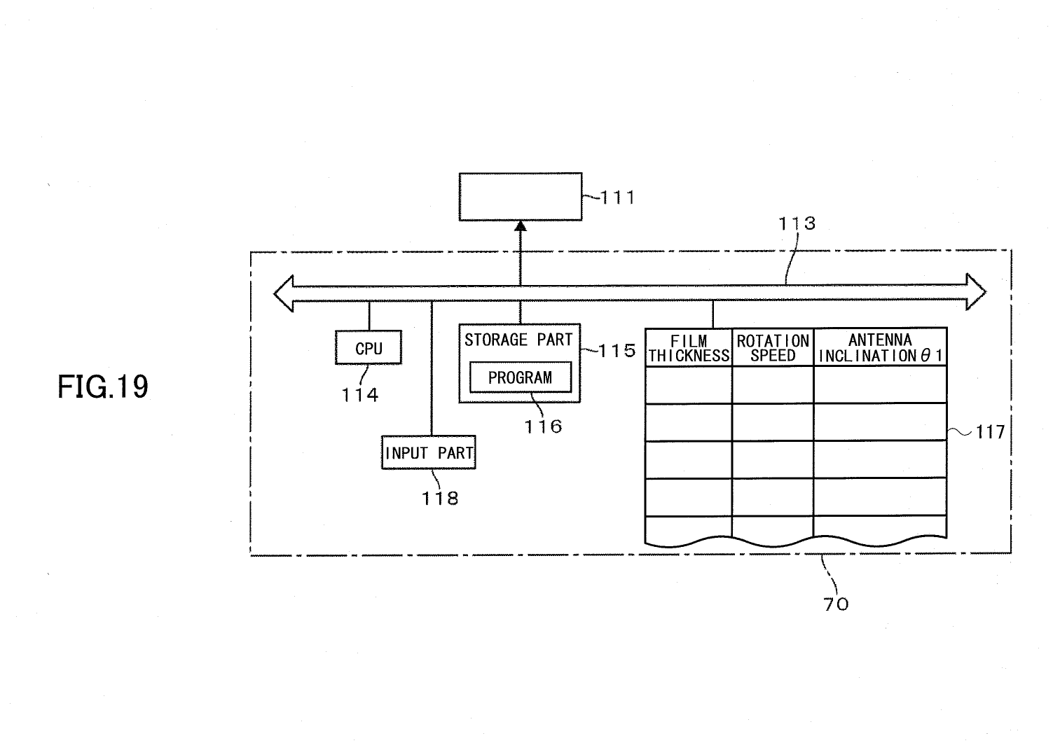

FIG. 19 is a block diagram showing a configuration of the control part 70. In FIG. 19, the control part 70 includes a bus 113, a CPU 114, and a program storage part 115 that stores a program 116. The control part 70 further includes a table 117 storing a correspondence relationship among a film thickness (nm) of the SiO₂ film deposited on the wafer W, a rotational speed (rpm) of the turntable 2 for depositing the SiO₂ film, and the antenna inclination θ1. The control part 70 further includes an input part 118 constituted of, for example, a keyboard, a touch panel, and the like. A user can set an intended film thickness and the rotational speed from this input part 118.

The program 116 contains instructions to control operation of the drive mechanism 111 based on settings set from the input part 118 other than instructions to control the operation of respective parts of the film deposition apparatus 1 as well as the first embodiment. More specifically, upon receiving the film thickness and the rotational speed input from the input part 118, an antenna inclination θ1 corresponding to these input values is read from the table 117, and the drive mechanism 111 operates to incline the antenna 44 so as to be the read inclination θ1. Then, the film deposition process is started as described in the first embodiment; the turntable 2 is rotated at a set rotational speed; the plasma is generated at a distribution in accordance with the inclination of the antenna 44; and the SiO₂ film with a set film thickness is obtained. A series of these processes is controlled by the program 116. Even when the film deposition apparatus is configured in this manner, a high uniformity process can be implemented on the surface of the wafer W similarly to the above respective embodiments. Here, the relationship among the film thickness, the rotational speed, and the inclination θ1 is obtained by measuring preliminarily.

Moreover, the description is given about an example of the silicon oxide film being deposited by using the Si containing gas and the O₃ gas in the above embodiments; but for example, a silicon nitride film may be deposited by using the Si containing gas for the first process gas, and an ammonia (NH₃) gas for the second process gas. In this case, an argon gas and one of the nitrogen gas and the ammonia gas and the like are used for the process gases to generate the plasma.

Furthermore, a titanium nitride (TiN) film may be deposited by using a titanium dichloride (TiCl₂) gas for the first process gas, and the ammonia (NH₃) gas for the second process gas. In this case, a substrate made of the titanium is used as the wafer W, and the argon gas, the nitrogen gas and the like are used as the plasma generating gas to generate the plasma.

In addition, a reaction product may be deposited by supplying three kinds or more of process gases in turn. More specifically, for example, after supplying a Sr material such as a strontiumbis-tetramethylheptanedionato (Sr(THD)₂) gas or a bis(pentamethyl)cyclopentadienestrontium (Sr(Me₅Cp)₂) gas and a Ti material such as a titaniumbis(isopropoxide)bis-tetramethylheptanedionato (Ti(OiPr)₂(THD)₂) gas or titaniumtetra(isopropoxide) (Ti(OiPr) gas, a thin film made of a STO film to be an oxide film including a Sr and a Ti may be deposited in a layer-by-layer manner by supplying the O₃ gas on the wafer W.

In the film deposition apparatus of the above embodiments, the N₂ gas is supplied from the gas nozzles 32, 35 to the separation area D. However, as for the separation area D, the gas nozzles may not be arranged by providing a wall part to divide between the respective process areas P1 and P2. In addition, as discussed above, blocking the electric field by providing the Faraday shield 51 is preferable, but performing the process without providing the Faraday shield 51 is possible.

A plasma etching resistance material such as alumina (Al₂O₃) or yttria may be used as a material for forming the casing 61 instead of the quartz, or the casing 61 may be made of heat resistant glass such as Pyrex glass (Trademark) coated with these plasma etching resistance materials on the surface thereon. In other words, the casings 61 may be made of a material (dielectric material) that has a high plasma resistance and transmits a magnetic field. In addition, the Faraday shield 51 is isolated from the antenna 44 by arranging the insulating member 59 on the upper side of the Faraday shield 51 in the above-mentioned examples, but for example, the antenna 44 may be coated with an insulating material such as quartz instead of arranging the insulating member 59.

In the above embodiments, the description is given about an example of performing the alteration of the reaction product by the plasma generation part 4 after supplying the Si containing gas and the O₃ gas on the wafer W in this order, but the O₃ gas used in depositing the reaction product may be converted to plasma. In other words, by supplying the O₃ gas from the gas nozzle 34 without providing the gas nozzle 33, the oxidation of the Si and the alteration of the SiO₂ may be implemented in the plasma formation area 68.

In the above embodiments, though the film deposition of the reaction product and the alteration process of the reaction product are performed alternately, for example, about 70 layers (film thickness of about 10 nm) of the reaction products are deposited first, and then the alteration process may be performed on the layered reaction products, which can have an equivalent effect. More specifically, supplying the radio frequency power to the antenna 44 is stopped while performing a film deposition process of the reaction product by supplying the Si containing gas and the O₃ gas. Then, after forming a layered film, supplying the Si containing gas and the O₃ gas is stopped, and the plasma process is performed on the wafer W by supplying the radio frequency power to the antenna 44.

In the above examples, the film deposition apparatus is described as an embodiment of the substrate processing apparatus, but the substrate processing apparatus is not limited to the film deposition apparatus 1. For example, the substrate processing apparatus may be configured to be an etching apparatus. More specifically, the substrate processing apparatus is configured to include two of the plasma generating parts 4 provided at two places in the circumferential direction so as to carry out the plasma process at the two places. The plasma formation areas 68 formed by the respective plasma generating parts 4 are made a first plasma formation area and a second plasma formation area. The gas nozzle 34 provided in the first plasma formation area supplies, for example, a Br (bromine) system etching gas for etching a poly silicon film, and the gas nozzle 34 provided in the second plasma formation area supplies, for example, CF system etching gas for etching a silicon oxide film.

For example, poly silicon films and silicon oxide films are alternately deposited on the wafer W, and a resist film in which a hole or a trench is patterned is formed on the upper layer of these layered films. When the plasma etching process is performed on the wafer W by using the substrate processing apparatus, for example, the poly silicon film on the upper layer side of the layered films is etched through the resist film in the first plasma formation area. Next, in the second plasma generating area, the silicon oxide film on the lower layer side of the poly silicon film is etched thorough the resist film. In this manner, by the rotation of the turntable 2, the layered films are etched in turn from the upper layer side toward the lower layer side though the common resist film. Even in this etching apparatus, because a processed amount by the plasma can be made uniform in the surface of the wafer W similarly to the film deposition apparatus 1, the high uniformity process can be performed within the surface of the wafer W. Moreover, when the first plasma formation area and the second plasma formation area are formed in such a manner, by supplying different gases from the respective areas to the turntable 2, the alteration process of the surface of the wafer W may be performed in the respective areas.

[First Evaluation Test]

A SiO₂ film is deposited on a wafer W in accordance with the above-mentioned procedure, using a film deposition apparatus 1 in which shapes of a coil-type electrode 45 in an antenna 44 are respectively changed. The SiO₂ film is measured in thickness at plural positions on a diameter from the outer edge to the rotation center of the turntable 2 in the wafer W. A film is not previously formed on a surface of the wafer W used for the film deposition process, and the entire wafer W is made of silicon. Five kinds of the coil-type electrode 45 are made by winding around metal wires three times to be formed in an octagonal shape in a planar shape similarly to the respective embodiments, and degrees of bending in a vertical direction are varied respectively. The respective antennas 44 are expressed as antennas 44A through 44E.

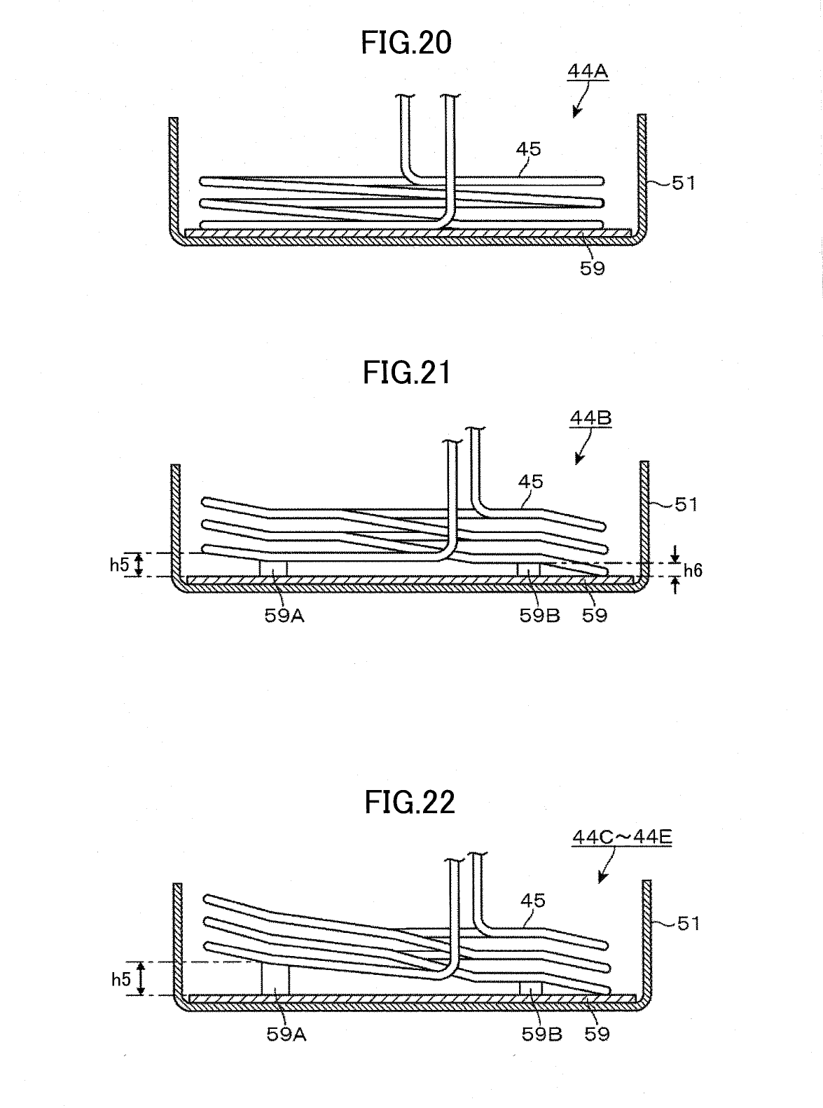

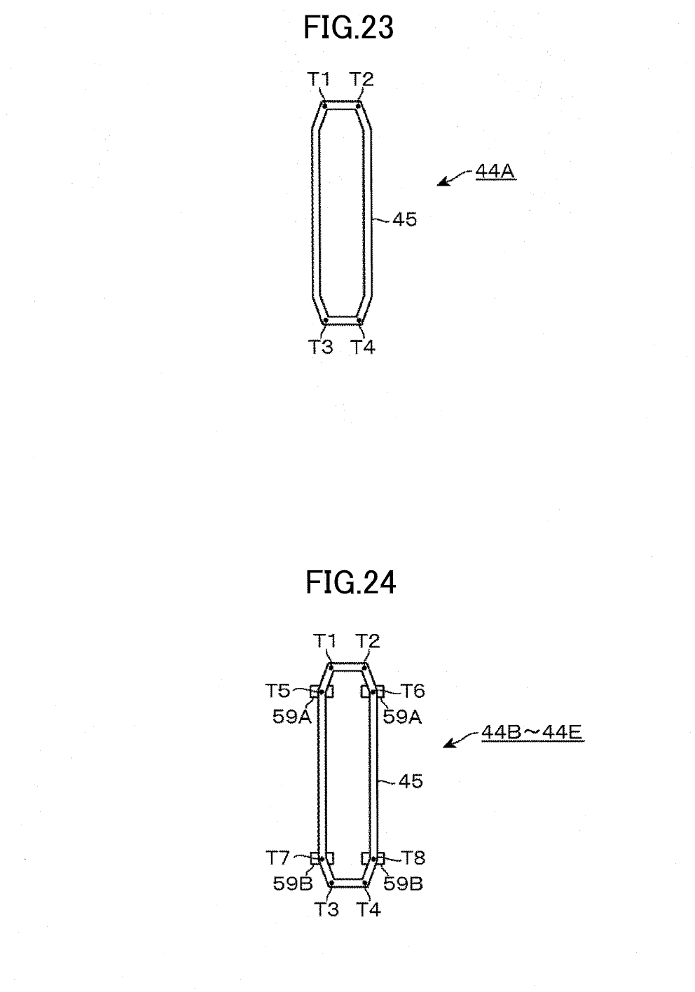

FIG. 20 shows an outline side view of the antenna 44A; FIG. 21 shows and outline side view of the antenna 44B; and FIG. 22 shows outline side views of the antennas 44C through 44E. In these FIGS. 20 through 22, the left side shows the center side of the turntable 2, and the right side shows the outer edge side of the turntable 2. Furthermore, FIG. 23 shows an outline top view of the coil-type electrode 45 of the antenna 44A, and FIG. 24 shows a top view of the coil-type electrode 45 of the antennas 44B through 44E. In the respective FIGS. 23 and 24, the top side is the rotation center side, and the lower side is the outer edge side of the turntable 2.

In the antenna 44A, the lowest metal wire contacts an insulating member 59 from the rotation center side to the outer edge side as seen from a side perspective. In FIG. 23, points T1 through T4 on the surface of the metal wire on the upper stage side are shown, and heights of any of these points T1 through T4 from the insulating member 50 are all 30 nm. As shown in FIG. 23, the antenna 44A is configured in a way that the coil-type electrode 45 of the antenna 44A is bent upward on the rotation center side and downward on the outer edge side. These bending positions are respectively at 50 mm from the end on the rotation center side of the coil-type electrode 45 (which is made an antenna tip part) and from the end on the outer edge side (which is made an antenna base part). A height h5 from the insulating member 59 to the lower end of the antenna tip part is 6 mm, and in the metal wire of the lowest end of the coil, a height h6 from the bending position on the antenna base part side to the lowest end of the antenna base part is 2 mm. Moreover, in FIG. 24, heights of points T1 through T8 from the insulating member 59 are 34 mm, 34 mm, 30 mm, 30 mm, 30 mm, 32 mm, 35 mm, and 36 mm in turn. In FIG. 24, pedestals 59A, 59B are respectively arranged on the rotational side and on the outer edge side, and support the coil-type electrode 45 from the bottom. The pedestals 59A, 59B are made of quartz, and the height is 2 mm.

The antennas 44C through 44E are configured to be similar to the antenna 44B, but the rotation center side of the coil-type electrode 45 is bent to be raised higher than that of the antenna 44B. In addition, a height of the pedestal 59A is made 4 mm. A description is given below about other different points from the antenna 44B. The height h5 of the antenna 44C is 10 mm, and heights of the points T1 through T8 from the insulating member 59 are 37 mm, 37 mm, 30 mm, 30 mm, 35 mm, 34 mm, 34 mm, and 35 mm in turn. In the antenna 44D, the height h5 is 8 mm, and the respective heights of points T1 through T8 are the same as those of the antenna 44C. The height h5 of the antenna 44E is 9.5 mm, and the respective heights of points T1 through T8 are the same as those of the antenna 44C.

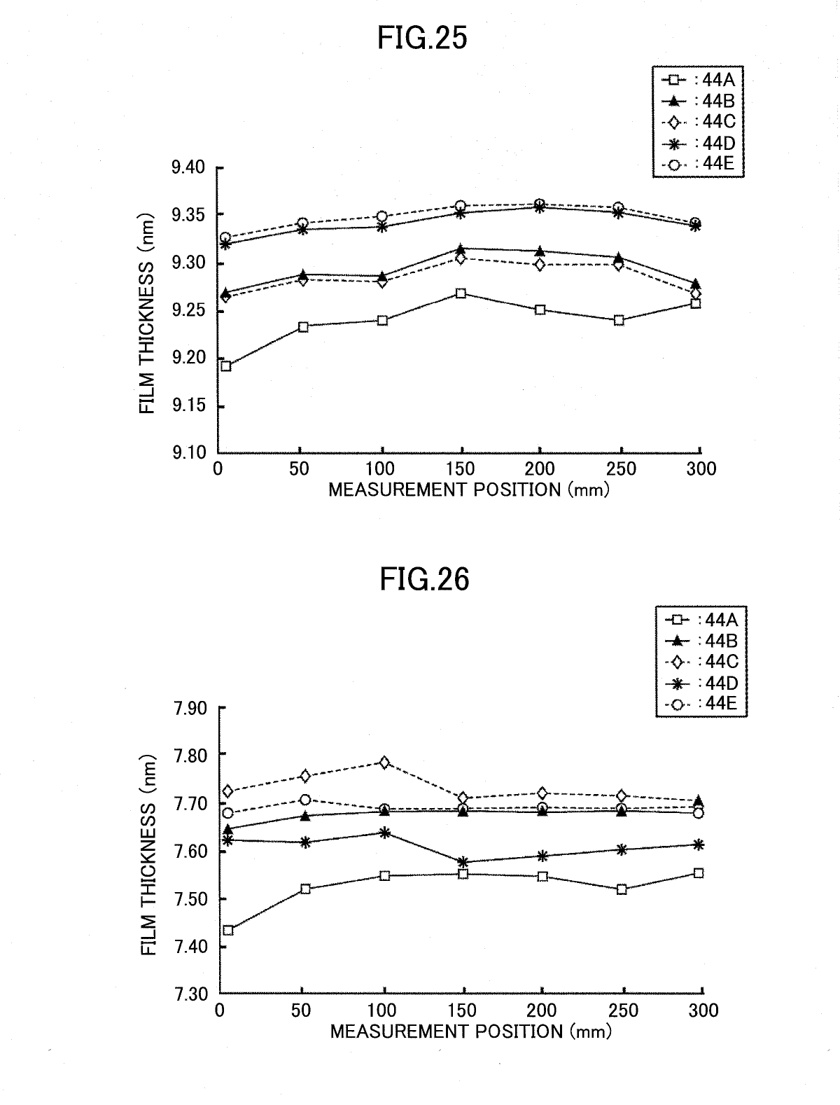

FIG. 25 is a graph showing a result of the evaluation test for each antenna that was used. The vertical axis shows a film thickness (nm) of the SiO₂ at each measurement position in the wafer W, and the horizontal axis shows the measurement position. The measurement position is expressed by a distance (mm) from the edge on the rotation center side of the turntable 2. In other words, points of 0 mm, 150 mm, and 300 mm in measurement position are respectively the end on the rotation center side of the wafer W, the center of the wafer W, and the end on the outer edge side of the turntable 2. According to this graph, in a process using the antenna 44A, a film thickness on the rotation center side was less than that on the outer edge side, and the difference of the film thicknesses was relatively high. However, in processes using the antennas 44B through 44E, the differences of these film thicknesses were decreased, which demonstrates that the processes were performed with a high degree of uniformity. It is considered that the plasma intensity was weakened on the rotation center side by using the antennas 44B through 44E, so that adsorption sites were distributed with a high degree of uniformity in the surface of the wafer W, even though the plasma intensity was so high that formation of the adsorption sites was substantially suppressed when the antenna 44A was used.

In the first evaluation test, average values of the film thicknesses at respective measurement positions of the respective processes having used the antennas 44A through 44E were 9.24 nm, 9.29 nm, 9.28 nm, 9.34 nm, and 9.35 nm in turn, and a significant difference was not found among the respective processes. However, when uniformity (=(a maximum value of measurement values−a minimum value of the measurement values)/(an average value*2)*100) was calculated, in the processes having used the antennas 44A through 44E, 0.40, 0.25, 0.21, 0.22, and 0.20 are obtained in turn. In short, the uniformity of the film thickness was the lowest in the process having used the antenna 44A, and the highest in the process having used the antenna 44E among the processes having used the antennas 44A through 44E.

[Second Evaluation Test]

An experiment similar to the first evaluation test was performed except that an oxide film was formed on a surface of a wafer W. FIG. 26 is a graph showing a result of the second evaluation test. Similarly to the result of the first evaluation test, in a process by the antenna 44A, a film thickness on the rotation center side was lower than that on the outer edge side, and the difference of these film thicknesses was relatively large. However, in processes having used the antenna 44B through 44E, the differences between the film thickness on the rotation center side and that on the outer edge side were reduced. Moreover, average values at respective measurement positions of processes having used the antenna 44A through 44E were 7.52 nm, 7.67 nm, 7.73 nm, 7.60 nm, and 7.68 nm in turn, and a significant difference among respective processes was not found, but the uniformities were 0.80, 0.42, 0.58, 0.39, and 0.20. To sum up, the process having used the antenna 44A had the lowest uniformity in film thickness, and the process having used the antenna 44E had the highest uniformity in film thickness.

[Third Evaluation Test]

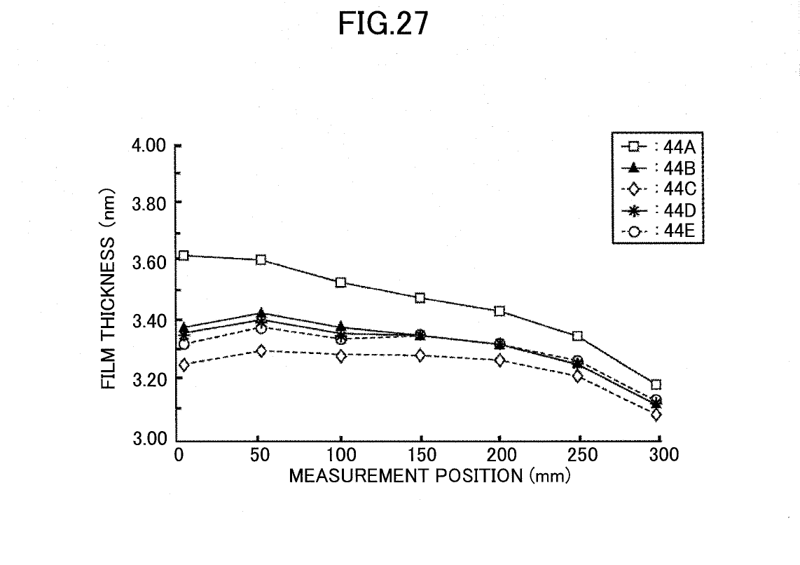

A process similar to the first evaluation test was performed except that the process gas nozzle 31 did not supply the Si containing gas, and a film thickness of a SiO₂ film formed by oxidation of Si on a surface of a wafer W was measured. FIG. 27 is a graph showing a result of the third evaluation test. According to this graph, in a process by the antenna 44A, a film thickness on the rotation center side was greater than that on the outer edge side. In other words, the plasma intensity was higher on the rotation center side than on the outer edge side, and oxidation was more developed on the rotation center side than on the outer edge side. In processes having used the antennas 44B through 44E, film thicknesses on the rotation center side were thicker than those on the outer edge side, but the film thicknesses on the rotation center side were less than the result of the antenna 44A, and a difference between the film thickness on the rotation center side and that on the outer edge side was low. In other words, it was found that when the antennas 44B through 44E were used, the plasma intensity on the rotation center side became lower than that when the antenna 44A was used, and a high uniformity oxidation process was performed on the wafer W.

Averages of the film thicknesses at respective measurement points of the processes having used the antennas 44A through 44E were 3.46 nm, 3.32 nm, 3.25 nm, 3.32 nm, and 3.31 nm in turn, and a significant difference among the respective processes was not found. However, when the antennas 44A through 44E were used, calculated uniformities were respectively 6.40, 4.39, 3.22, 4.07, and 3.65. In short, the process having used the antenna 44A had the lowest uniformity of the film thickness, and the process having used the antenna 44C had the highest uniformity of the film thickness among the processes.

From the results of the first through third evaluation tests, it is found that the plasma distribution can be controlled and the high uniformity process can be performed on the wafer by bending the rotation center side of the antenna 44 so as to be more distant from the turntable 2 than the outer edge side. Hence, effects of the embodiment of the present invention were shown.

In this manner, according to embodiments of the present invention, an antenna for plasma formation facing a substrate mounting area of a turntable is provided so as to extend from the center part to the outer edge part of the turntable, and a distance on the center side of the turntable of the antenna in the substrate mounting area is larger than that on the outer edge side. Therefore, the substrate loaded on the turntable is exposed by plasma with relatively low intensity for a relatively longer period on the center side of the turntable, and is exposed by plasma with relatively high intensity for a relatively shorter period on the outer edge side of the turntable. As a result, a process such as a film deposition can be performed with a high degree of uniformity.

All examples recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiments of the present invention have been described in detail, it should be understood that the various changes, substitutions, and alterations could be made hereto without departing from the spirit and scope of the invention.

What is claimed is:

1. A film deposition apparatus configured to perform a film deposition process on a substrate by rotating a turntable holding the substrate on a substrate mounting area to pass the substrate through plural process areas in turn, thereby performing a cycle of supplying plural kinds of process gases in turn in a vacuum chamber, the film deposition apparatus comprising:
a gas supplying part configured to supply a plasma generating gas on a surface on the substrate mounting area side in the turntable; and
an antenna configured to convert the plasma generating gas to plasma by induction coupling, the antenna being provided facing the surface of the substrate mounting area side in the turntable so as to extend from a center part to an outer edge part of the turntable, the antenna being arranged so as to have a distance from the turntable in the substrate mounting area 3 mm or more longer on the center part side than on the outer edge part side.

2. The film deposition apparatus as claimed in claim 1,
wherein the antenna has a bent shape so as to be higher on the center part side of the turntable than any other part with respect to the surface of the turntable.

3. The film deposition apparatus as claimed in claim 1,
wherein the antenna is formed by being wound around a vertically extending axis in a coil-like shape,
and at least the lowest part of the antenna is in the outer edge part side.

4. The film deposition apparatus as claimed in claim 1, further comprising:
a supporting part configured to support the antenna; and
an inclination adjustment mechanism configured to adjust an inclination of the antenna in a vertical direction through the supporting part.

5. The film deposition apparatus as claimed in claim 4,
wherein the inclination adjustment mechanism includes a drive mechanism configured to drive the inclination of the antenna.

6. The film deposition apparatus as claimed in claim 5, further comprising:
a control part configured to determine the inclination of the antenna in accordance with a kind of an input film deposition process, and to control the drive mechanism to cause the antenna to achieve the determined inclination.

7. The film deposition apparatus as claimed in claim 1,
wherein the antenna includes plural straight parts and a joint part for connecting the straight parts to each other, and is configured to be bendable at the joint part.

8. A substrate processing apparatus configured to perform a film deposition process on a substrate by rotating a turntable holding the substrate on a substrate mounting area to pass the substrate through plural process areas in turn, thereby performing a cycle of supplying plural kinds of process gases in turn in a vacuum chamber, the substrate processing apparatus comprising:
a gas supplying part configured to supply a plasma generating gas on a surface on the substrate mounting area side in the turntable; and
an antenna configured to convert the plasma generating gas to plasma by induction coupling, the antenna being provided facing the surface of the substrate mounting area side in the turntable so as to extend from a center part to an outer edge part of the turntable, the antenna being arranged so as to have a distance from the turntable in the substrate mounting area 3 mm or more longer on the center part side than on the outer edge part side.

9. The substrate processing apparatus as claimed in claim 8,
wherein the antenna has a bent shape so as to be higher on the center part side of the turntable than any other part with respect to the surface of the turntable.

10. The substrate processing apparatus as claimed in claim 8,
wherein the antenna is formed by being wound around a vertically extending axis in a coil-like shape,
and at least the lowest part of the antenna is in the outer edge part side.

11. The substrate processing apparatus as claimed in claim 8, further comprising:
a supporting part configured to support the antenna; and
an inclination adjustment mechanism configured to adjust an inclination of the antenna in a vertical direction through the supporting part.

12. The substrate processing apparatus as claimed in claim 11,
wherein the inclination adjustment mechanism includes a drive mechanism configured to drive the inclination of the antenna.

13. The substrate processing apparatus as claimed in claim 12, further comprising:
a control part configured to determine the inclination of the antenna in accordance with a kind of an input film deposition process, and to control the drive mechanism to cause the antenna to achieve the determined inclination.

14. The substrate processing apparatus as claimed in claim 8,
wherein the antenna includes plural straight parts and a joint part for connecting the straight parts to each other, and is configured to be bendable at the joint part.
